(19) United States
(12) Patent Application Publication
(10) Pub. No.: US 2024/0023360 A1
(43) Pub. Date: Jan. 18, 2024

(54) COLOR-TUNABLE OLED HAVING LONG OPERATIONAL LIFETIME

(71) Applicant: The University of Hong Kong, Hong Kong (CN)

(72) Inventors: Mao MAO, Hong Kong (CN); Chi-Ming CHE, Hong Kong (CN); Gang CHENG, Hong Kong (CN)

(21) Appl. No.: 18/251,364

(22) PCT Filed: Oct. 29, 2021
(86) PCT No.: PCT/CN2021/127397

§ 371 Date: May 1, 2023

Related U.S. Application Data
(60) Provisional application No. 63/107,530, filed on Oct. 30, 2020.

(51) Int. Cl. H10K 50/13; H10K 50/16; H10K 50/17; H10K 85/60; H10K 85/30; H10K 50/15; H10K 101/00; H10K 102/00

(52) U.S. Cl. CPC H10K 50/13; H10K 50/16; H10K 50/171; H10K 85/6572; H10K 85/615; H10K 85/346; H10K 85/633; H10K 50/15; H10K 2101/90; H10K 2102/351

(57) ABSTRACT

Disclosed are stable, high-efficiency voltage-dependent color-tunable organic light-emitting diodes with a single emitter, such as tetradentate platinum (II) complex, having long operational lifetime. High-performance voltage-dependent color-tunable OLEDs with a single Pt [O\hat{ }N\hat{ }C\hat{ }N] emitter are fabricated. The emission color can be tuned from warm white to nature white or from orange to yellowish green upon the emitter used. Long-term operational stability and continuously variable color enable these color-tunable OLEDs to find applications in smart wearable devices.

### TECHNICAL FIELD

Disclosed are color-tunable tetradentate platinum II emitters and OLEDs containing the tetradentate platinum II emitters.

### BACKGROUND

After their commercial success in display panels, organic light-emitting diodes (OLEDs) are expected to play a critical role in next-generation solid-state illumination and smart lighting, owing to their unique properties, such as flexibility, ultra-thin thickness and light weight. In addition to fixed chromaticity in ordinary illumination devices, there is a great demand for tunable chromaticity in certain applications, such as smart lighting, decoration and botanical grow lamps. Specifically, the voltage-dependent, color-tunable OLED is an appealing tool for the visualization of the electronic output signal of sensors, such as real-time wearable electrocardiogram monitors and electronic skin sensors.

As shown in FIG. 1, several strategies for the construction of color-tunable OLEDs have been proposed in the literature. Among these strategies, the most straightforward is the combination of multiple, independently controlled sub-OLED arrays in parallel or tandem way (FIGS. 1a and 1b). Known is a tandem color-tunable device structure with two independently controlled orange and blue sub-OLEDs that share a common electrode. This device can achieve a wide color-span range, from blue via white to orange, and has a high power efficacy (PE) of 36.8 lm W⁻¹ by using alternating current as the power source. Nonetheless, this kind of device has a sophisticated device structure, thereby leading to a potentially high fabrication cost and low long-term stability. A single-cell device structure with multiple emitters, that can be selectively activated at different driving voltages, is a simpler choice for color-tunable OLEDs. Several mechanisms have been proposed in the literature to explain the color-shift phenomenon of this type of OLED, such as the move of the exciton recombination zone from one emitting layer (EML) to another, in the devices with multiple EMLs (FIG. 1c), as well as a competition between charge-trapping emission and energy-transfer emission, or the change of energy transfer rate between different emitters in the devices with a single EML (FIG. 1d). Compared to the color-tunable OLEDs combined with multiple sub-OLEDs, the single-cell varieties usually possess relatively low efficiency and/or pronounced efficiency roll-off. For instance, although a high external quantum efficiency (EQE) of up to 22.02% was achieved in a color-tunable OLED, by co-doping a yellow-emitting Au(III) complex and a blue-emitting Ir(III) complex in a shared host, the EQE value plummeted at high luminance due to the saturation of the emissive excited state of the Au(III) emitter. In addition, the color-aging limitation potentially arises due to differential operating lifetimes of the multiple emitters used in the reported color-tunable OLEDs. In principle, such a color-aging issue can be avoided by simplifying the device structure that requires only a single emitter (FIG. 1e).

As the single emitter is the crucial component of this kind of device, a qualified one should fulfill two criteria; i) have the ability to emit both high-energy and low-energy light at the same time, in order to guarantee a wide color-span range; ii) exhibit high efficiency and short emission lifetime for both high-energy and low-energy emission to achieve high electroluminescent (EL) efficiency at a practical luminance of 1000 cd m⁻². Among the literature-reported high-efficiency emitters for OLEDs, platinum(II) complexes can fulfill both criteria, due to their planar molecular structure: i) Pt(II) complexes have a strong propensity toward aggregation via π-π stacking and/or metal-metal interactions that give rise to new triplet metal-metal-to-ligand charge transfer (³MMLCT) emission in the low-energy spectral region, and ii) phosphorescence from Pt(II) emitters in aggregated forms generally features markedly enhanced radiative decay rate constants and much shorter emission lifetimes, compared to monomer emission, owing to the increased metal character in the emissive 3 MMLCT excited state.

### SUMMARY

The following presents a simplified summary of the invention in order to provide a basic understanding of some aspects of the invention. This summary is not an extensive overview of the invention. It is intended to neither identify key or critical elements of the invention nor delineate the scope of the invention. Rather, the sole purpose of this summary is to present some concepts of the invention in a simplified form as a prelude to the more detailed description that is presented hereinafter.

A color-tunable OLED having long operational lifetime is described herein. By tuning driving voltage or current, the emitting wavelength of OLEDs can be changed, and further the emitting color or color temperature can be tuned.

Various principles support the subject matter described herein.
1) a. the single emitter could form two states: monomer state and aggregation state
   b. the single emitter could form monomer or interact with other materials and form exciplex
   c. the single emitter is metal complex, such as Pt-complexes or Pd-complexes, or organic TADF complex with aggregation emission.
2) when applying low voltage, the emission spectra of OLEDs will be dominated by low-energy aggregation emission/exciplex emission.
3) with the increase of driving voltage, the OLEDs can emit high-energy monomer-state light, and the emission will be gradually enhanced, even dominate the OLEDs emission
4) because this method just utilize the emission of single emitter's different state, the color-tunable characteristic can reverse and repeat.
5) thanks to the stable device structure and stable emitter, the device operational lifetime is long (LT50>200, 000 hr at 100 cd/m²), which can meet the requirement of practical use in wearable device or the display of monitor for physical health.

Disclosed herein are tetradentate platinum II based emitters having a first emission wavelength when subjected to a first driving voltage and a second wavelength different from the first wavelength when subjected to a second driving voltage different from the first driving voltage.

Also disclosed are organic light-emitting diode, containing a first functional layer and a second functional layer configured to have a voltage driven across the first functional layer and the second functional layer; and an emissive layer between the first functional layer and the second functional layer, the emissive layer comprising a tetradentate platinum II based emitter having a first emission wavelength when subjected to a first driving voltage and a second wavelength different from the first wavelength when subjected to a second driving voltage different from the first driving voltage.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF SUMMARY OF THE DRAWINGS

FIG. 1 depicts schematic diagrams of different strategies for color-tunable OLEDs. a) an independently controlled tandem sub-OLED array; b) an individually controlled parallel sub-OLED array; c) a single OLED cell with multiple emissive layers; d) a single OLED cell with multiple emitters in a single emissive layer; and e) a single OLED cell with a single emitter in a single emissive layer.

FIG. 2 depicts the chemical structures of Pt-X-2, Pt-X-3 and Pt-X-4 in accordance with an aspect of the invention.

FIG. 3 graphically reports the normalized EL spectra at the indicated driving voltages, ranging from 3 to 11 V, for color-tunable OLEDs with EMLs consisting of a) TCTA: B3PYMPM: Pt-X-3 (20 nm, 6 wt %), b) TCTA: B3PYMPM: Pt-X-3 (20 nm, 12 wt %), c) TCTA: B3PYMPM: Pt-X-3 (10 nm, 6 wt %)/TCTA: B3PYMPM: Pt-X-3 (10 nm, 12 wt %) or d) TCTA: B3PYMPM: Pt-X-3 (10 nm, 12 wt %)/TCTA: B3PYMPM: Pt-X-3 (10 nm, 6 wt %).

FIG. 4 graphically reports the dependence of Aagg/mon on driving voltage of traditional co-host OLEDs with a Pt-X-3 emitter at the indicated doping concentrations of 6 and 12 wt %. Solid squares represent experimental data, the solid red lines represent theoretical fitting results, and the blue dashed lines indicate the turn-on voltage of both devices.

FIG. 5 graphically reports normalized EL spectra of color-tunable OLEDs with CHIDEL structure based on a) Pt-X-2 and b) Pt-X-4. c) Color-shift of OLEDs with Pt-X-2, Pt-X-3 and Pt-X-4, upon increasing driving voltage.

FIG. 6 depicts a) EQE-luminance characteristics of color-tunable OLEDs with Pt-X-2, Pt-X-3 and Pt-X-4, and b) EL patterns of Pt-X-4 in OLEDs with conventional single EMLs with co-host TCTA: B3PYMPM at 8 and 18 wt %; the solid black line represents the Lambert distribution.

FIG. 7 reports Table 1: Key performance characteristics of color-tunable OLEDs with CHIDEL structure.

FIG. 8 graphically shows current density-voltage characteristics of Pt-X-3 devices with different doping concentrations of 3, 9, and 12 wt %. The EML of these devices was constructed with traditional single co-host TCTA: B3PYMPM.

FIG. 9 graphically shows PL spectrum of a 100-nm-thick film of Pt-X-3 doped in co-host TCTA: B3PYMPM with 12 wt % doping concentration.

FIG. 10 graphically shows normalized EL spectra of Pt-X-3 with TCTA: T2T as the co-host in traditional structure devices with a) 6 and b) 12 wt % dopant concentrations.

FIG. 11 graphically shows EQE-current density characteristics of color tunable OLEDs with Pt-X-2, Pt-X-3 and Pt-X-4.

FIG. 12 depicts PL and EL spectra of Pt-X-2 (26 wt %) and Pt-X-4 (18 wt %).

FIG. 13 depicts a) Normalized EL spectra of the Pt-X-4 device with traditional single EML with co-host TCTA: B3PYMPM at a concentration of 8 wt % at different observation angels; b) EQE-luminance characteristics of Pt-X-4 device with traditional single EML with co-host TCTA: B3PYMPM at concentrations of 8 and 18 wt %.

FIG. 14 depicts operational lifetime of OLEDs based on Pt-X-4 with a dopant concentration of 8 wt %.

FIG. 15 depicts normalized EL spectra of the Pt-X-4 OLEDs used for lifetime measurement.

FIG. 16 graphically depicts the Luminance-U curves of device with Pt-X-4.

FIG. 17 reports characteristic data associated with a single tetradentate platinum(II) emitter having long operational lifetime.

FIG. 18 depicts chemical structures of the supporting organic materials used to construct the OLED described herein for lifetime measurement.

FIG. 19 depicts a system incorporating the color-tunable OLEDs described herein.

FIG. 20 (FIG. 20a-20e) depict the potential applications associated with the color-tunable OLEDs described herein (Ja, Hoon Koo, et al. ACS Nano 2017, 11, 10032-10041).

FIG. 21 (FIG. 21a-21d) depict potential wearable health-monitor device applications associated with the color-tunable OLEDs described herein (Ja, Hoon Koo, et al. ACS Nano 2017, 11, 10032-10041).

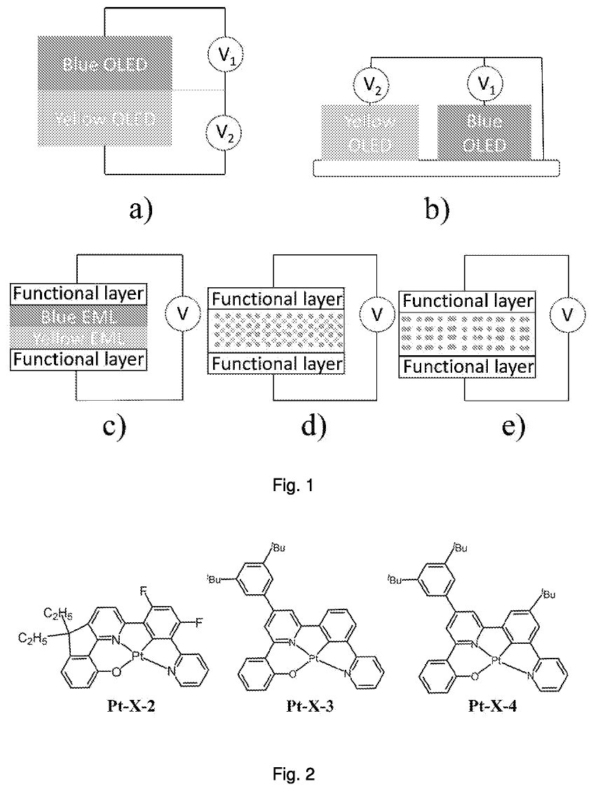

### DETAILED DESCRIPTION

Provided herein is a stable device structure and stable emitter to fabricate stable color-tunable OLED. Due to the broad spectrum of excimer emission or exciplex emission, this new OLED can achieve high CRI (>90) and emit different type of white colors at certain voltage, which is beneficial to smart OLED lighting. What is more, the stability of device operation is successfully solved with our device structure and stable emitter. The stable color-tunable OLED is a stable voltage-dependent color-tunable OLED, which can even meet the requirement of practical use in wearable smart device or smart lighting or decoration.

Various advantages include long operational device lifetimes with LT50>200,000 hr at 100 cd/m² (even much longer if the purity of materials is high enough), employing double hosts or double emissive layers to fabricate OLEDs, just utilizing single emitter to solve color-aging problem, and/or utilizing the two emission states of single emitter to emit large-range different color. The subject matter herein provides a simple way to fabricate stable voltage-dependent color-tunable OLED. The operational stability of color-tunable OLED can be leveraged in real-time variable displays for a wearable smart device.

Disclosed herein are a series of efficient phosphorescent Pt(II) emitters supported by tetradentate [O\hat{ }N\hat{ }C\hat{ }N] ligands. High EQEs of up to 26.8% were achieved in OLEDs based on the emission of such Pt(II) complexes. Among them, Pt-X-2, Pt-X-3, and Pt-X-4 (FIG. 2) all have the potential for use as single emitting dopant in the fabrication of voltage-dependent, color-tunable OLEDs, owing to the outstanding EL performance of the Pt[O\hat{ }N\hat{ }C\hat{ }N] complexes at both monomer and aggregation states. In the present study, we describe high-performance, color-tunable OLEDs with low-efficiency roll-off and wide color-span range, with a novel device structure. When Pt-X-4 was used as the single emitter, the emission color can be tuned from orange (3 V) to yellowish-green (11 V) with high EQEs of up to 23.23% and luminance beyond 90000 cd m⁻². At high luminance of 5000 and 10000 cd m⁻², efficiency roll-offs of the Pt-X-4 devices were low, at 9.38% and 19.97%, respectively. For the white OLEDs fabricated with Pt-X-2, the Commission International de I'Eclairage (CIE) coordinates shifted from (0.47, 0.44) to (0.36, 0.48). In addition, a high color rendering index (CRI) of 82, maximum EQE of 20.75% and maximum PE of 50.18 Im W⁻¹ were achieved with this device. At the practical luminance of 1000 cd m⁻² for illumination devices, the EQE value slightly decreased to 19.96%, corresponding to a roll-off of 3.8%. We attribute this improved efficiency roll-off of both devices to the high efficiency and short emission lifetime of the Pt[O\hat{ }N\hat{ }C\hat{ }N] in the aggregated state. Theory simulation with the trapping-and-energy-transfer model indicates that such a color-tunable phenomenon in the OLEDs with a single Pt-emitter may be the result of competition between charge-trapping and energy-transfer emission mechanisms.

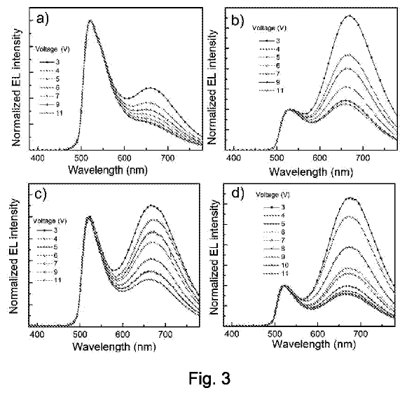

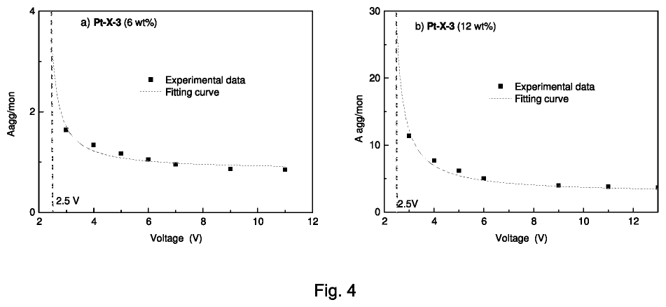

Considering its relatively simple molecular structure and well-studied concentration-dependent emission, Pt-X-3 was exploited to investigate the influence of device structure on EL performance in color-tunable OLEDs with a single Pt-emitter. As depicted in FIG. 3a and FIG. 3b, a color-tunable EL profile can be observed in a traditional co-host device structure of ITO/HAT-CN (10 nm)/TAPC (40 nm)/TCTA (10 nm)/TCTA: B3PYMPM: Pt-X-3 (20 nm)/B3PYMPM (10 nm)/TmPyPb (40 nm)/LiF (1.2 nm)/AI (100 nm) at both low (6 wt %) and high (12 wt %) dopant concentrations. In these devices, HAT-CN (1,4,5,8,9,11-hexaazatriphenylene hexacarbonitrile) was used as the hole-injecting layer, TAPC (1,1-bis-(4-bis(4-methylphenyl)-amino-phenyl)-cyclohexane) as the hole-transporting layer, TCTA (4,4′,4″-tris(N-carbazolyl)-triphenylamine) as the electron/exciton-blocking layer, B3PYMPM (bis-4,6-(3,5-di-3-pyridylphenyl)-2-methylpyrimidine) as the hole/exciton-blocking layer (EBL) and TmPyPB (1,3,5-tri(m-pyrid-3-yl-phenyl)) as the electron-transporting layer. The mixture of TCTA and B3PYMPM at a weight ratio of 1:1 was used as the co-host in the EML. At the low concentration of 6 wt %, the Pt-X-3 monomer emission located at around 527 nm dominated the EL spectrum, while its aggregation emission (³MMLCT emission), located at a lower-energy wavelength, decreased with an increase in driving voltage, leading to a color shift from CIE coordinates of (0.39, 0.57) at 3 V to (0.35, 0.60) at 11 V. A similar color shift from CIE coordinates of (0.54, 0.45) at 3 V to (0.35, 0.60) at 11 V was found for the Pt-X-3 device with a higher Pt(II) dopant concentration of 12 wt % (FIG. 3b). Despite the different dominant emission bands and the wider color-span range, the spectral shift trend for the device with 12 wt % Pt-X-3 was the same as that of the one with 6 wt %.

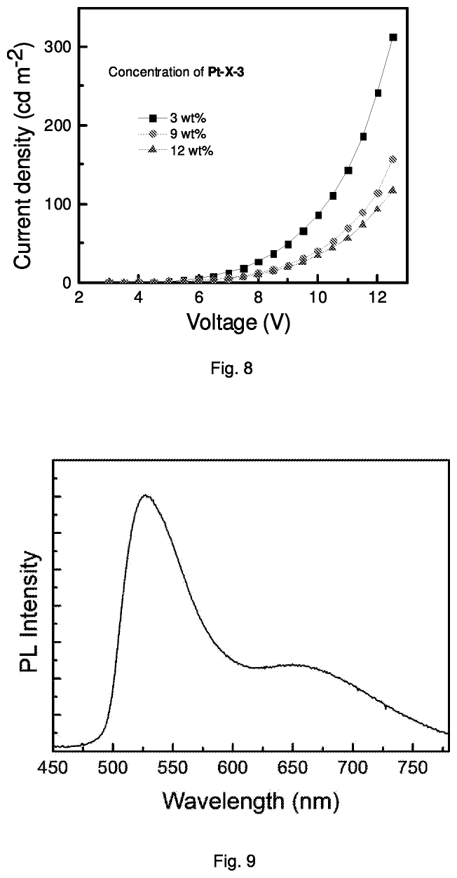

To quantitatively address the shift in EL spectrum of both Pt-X-3 based devices, we applied “Gaussian” fitting to estimate the ratio of aggregation emission to monomeric emission. At a low driving voltage of 3 V, the EL spectrum of the device with 12 wt % Pt-X-3 was dominated by the aggregation emission, with an integral area ratio (A_{agg/mon}) of 11.4:1. With the increase in applied voltage to 11 V, the A_{agg/mon} declined to 3.66:1. On the other hand, the A_{agg/mon} in the EL spectrum of the device with 6 wt % Pt-X-3 was 1.64:1 at 3 V and dropped to 0.85:1 at 11 V. As depicted in FIG. 8, the current density of the Pt-X-3 devices decreased with dopant concentration from 3 to 12 wt %, suggesting that charge-trapping is a primary emission mechanism in Pt-X-3-based devices. For charge-trapping OLEDs, excitons directly form and recombine on the emitting dopants without using the step of energy transfer from the electrically excited molecules of the host to the emitter. Compared to the devices based on energy transfer, the current density versus voltage characteristics of charge-trapping devices strongly depend on the dopant concentration because charge-trapping on emitting dopants decreases the charge carrier mobility in the EML. In addition, the photoluminescent (PL) spectrum of the sample with 12 wt % Pt-X-3 in the TCTA: B3PYMPM co-host shown in FIG. 9, Supporting Information, was quite different from the EL spectrum of Pt-X-3 at the same doping concentration (FIG. 3b); the monomer emission is much stronger than that of the aggregation emission in the PL spectrum while the aggregation emission is much stronger in the EL one. Such different spectrum profile between PL and EL of Pt-X-3 at the same dopant concentration suggested that charges were trapped in the aggregation states of Pt-X-3 during the EL process. Therefore, we applied the trapping-and-energy-transfer model to simulate the emission mechanism of color-tunable OLEDs fabricated with a Pt-X-3 single emitter. In a charge-trapping-controlled device, charged carriers are trapped and recombined at low-energy dopant (aggregated Pt-X-3, here) when low voltage is applied, leading to an EL spectrum dominated by aggregation emission. With the increase in driving voltage, the low-energy traps are gradually filled by increased injected carriers until saturation. At this stage, the high-energy emission from the excitons recombined at the high-energy dopant (monomeric Pt-X-3, in this case) gradually increases. Thus, the emission ratio A_{agg/mon} decreases with the increasing driving voltage. Such a trapping-and-energy-transfer model can be expressed by Equation 1.

$$q ( U ) = \frac{D}{μ} {( \frac{d}{{L}_{T}} )}^{2} \frac{1}{U - {U}_{0}} + \frac{d}{{L}_{T}} \qquad ( 1 )$$

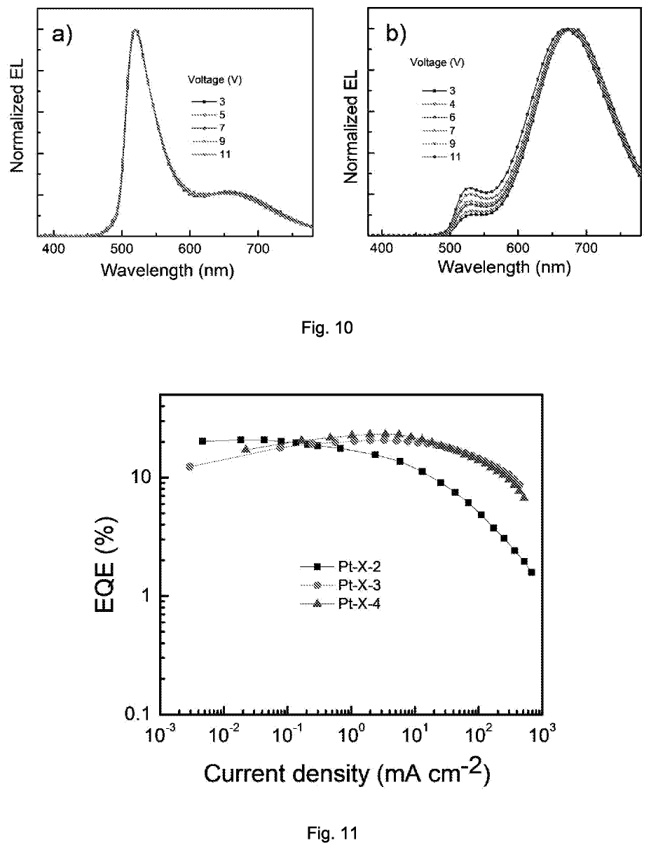

Equation 1 was derived for single-layer polymer OLEDs by Meerholz and co-workers, and applied by Wang and co-workers to multilayer OLEDs to account for color-tunable OLEDs. Instead of merely using the intensity ratio of different emission bands, as in previous literature reports, here we used the integral area ratio A_{agg/mon} to describe the emission ratio q(U) in Equation 1. We employed this methodology because the full width at half maximum (FWHM) of the aggregated emission of Pt-X-3 is greater than that of the monomer emission, which can cause a severe deviation during the simulation if the intensity ratio is used to describe q(U). In Equation 1, D is the diffusion coefficient of the trapped electrons, μ the mobility of the carriers, d the thickness of the EML, L_{T} the average diffusion distance before a carrier reaches a trapping center, U the driving voltage, and U₀ the built-in electronic field. Dip is the Einstein relation that describes the ratio between diffusivity and mobility. By using Equation 1 to fit the experimental data from the device with 12 wt % Pt-X-3, the curve fitting matches the experimental data with a correlation coefficient R² of 0.96, as shown in FIG. 4. This result validates the trapping-and-energy-transfer model in describing the EL process in Pt-X-3 devices. Here, we obtained a built-in field U₀ of 2.2 V and an Einstein relation D/μ of 1.2, which is close to that reported in conventional organic systems. For the device with 6 wt % Pt-X-3, the correlation coefficient R², built-in field U₀, and Einstein relation D/μ were 0.91, 2.2 V, and 1.2, respectively. It is notable that such a color-shift EL of Pt-X-3 in the TCTA: B3PYMPM host was not applicable for a random host. As depicted in FIG. 10, the EL spectrum was stable at low dopant concentration while slightly shifted at high dopant concentration, with increased driving voltage, when the mixture of TCTA:2,4,6-tris(biphenyl-3-yl)-1,3,5-triazine (T2T) was used as the co-host to replace TCTA: B3PYMPM, probably due to the relatively higher-lying HOMO (highest occupied molecular orbital) level of T2T, in which the aggregation form of Pt-X-3 was unable to trap charges effectively. Similarly, stable white emission has been reported for Pt-X-2 OLEDs with the TCTA: 2,6-bis(3-(9H-carbazol-9-yl)phenyl)pyridine (26DCzPPy) co-host, while color-tunable white emission could be realized when TCTA: 26DCzPPy was replaced by TCTA: B3PYMPM as the co-host in the EML. The details of this color-tunable white device are discussed below.

Since the ratio of aggregated/monomer states of Pt-X-3 was fixed at a fixed dopant concentration, the color-span would be limited within a relatively narrow spectral range, if a traditional co-host device structure was used. To further widen the color-span range of the Pt-X-3 devices, we designed a novel co-host in double-emissive layer (CHIDEL) device structure by combining two mechanisms that enable color-tunable devices: recombination-zone-shift and trapping-and-energy-transfer. In CHIDEL devices, the single EML in traditional co-host devices is replaced by two consecutive sub-EMLs with the same co-host system, but different dopant concentrations. In our case, the CHIDEL device structure was ITO/HAT-CN (10 nm)/TAPC (40 nm)/TCTA (10 nm)/TCTA: B3PYMPM: Pt-X-3 (x wt %, 10 nm)/TCTA: B3PYMPM: Pt-X-3 (y wt %, 10 nm)/B3PYMPM (10 nm)/TmPyPb (40 nm)/LiF (1.2 nm)/AI (100 nm). A bilayer TCTA: B3PYMPM: Pt-X-3 (x wt %, 10 nm)/TCTA: B3PYMPM: Pt-X-3 (y wt %, 10 nm) was used as the EML while x and y represent the doping concentrations of Pt-X-3 in the two sub-EMLs. Two concentration (x/y) combinations of 6/12 and 12/6 were examined; the normalized EL spectra at different driving voltages are shown in FIG. 3c, 3d. At a low driving voltage of 3 V, the EL spectrum of the 12/6 CHIMEL device was almost identical to that of the 12 wt % co-host device, suggesting that the excitons mainly formed in the sub-EML, adjacent to the TCTA layer, in the 12/6 CHIMEL device. With increasing driving voltage, the intensity of the Pt-X-3 monomer emission quickly increased, and its relative intensity was much stronger than that of the 12 wt % co-host device at a high voltage of 11 V (FIG. 3b, 3d), which is attributable to the expansion of the recombination zone to the 6 wt % sub-EML. For the 6/12 CHIMEL device, on the other hand, the relative intensity of the aggregation emission at the low driving voltage of 3 V was stronger than that of 6 wt % co-host device (FIG. 3a, 3c). Such a stronger aggregation emission may be the result of the stronger trapping effect of the 12 wt % sub-EML, leading to an inferior color-span range when compared to that of the 12/6 CHIMEL device.

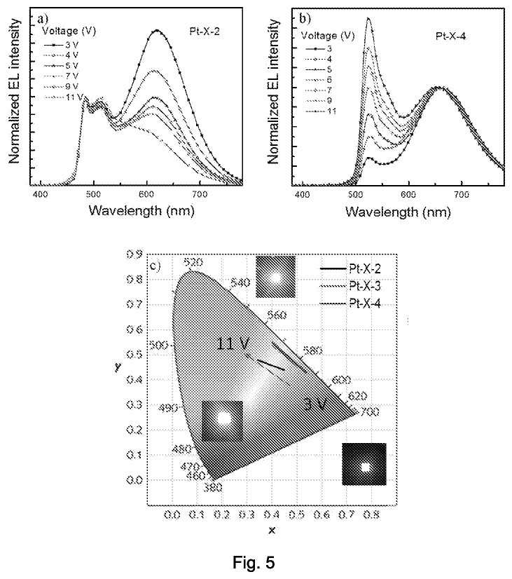

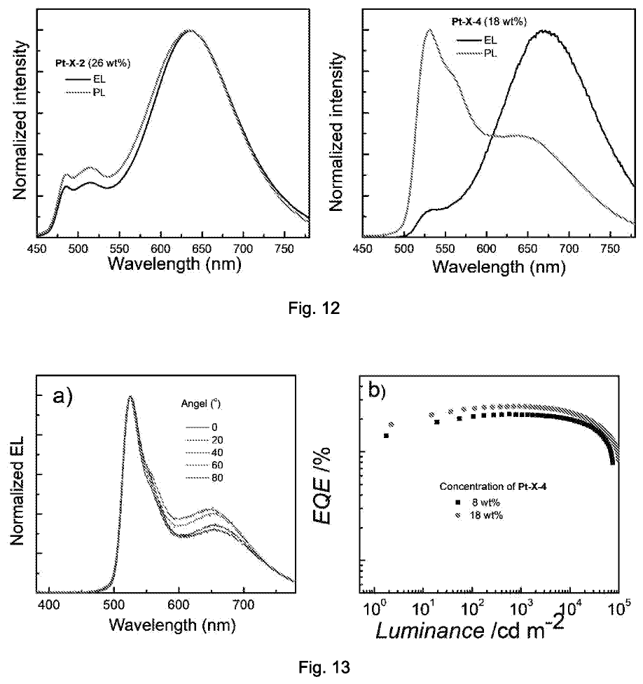

Despite the wide color-span range of the Pt-X-3 device with the optimized CHIDEL structure, the following weaknesses of Pt-X-3 limited its application: 1) The monomer emission (527 nm) of Pt-X-3 is not blue enough to produce a “true” white light spectral profile when combined with its lower-energy aggregation emission, limiting its application in illumination devices, and 2) The photoluminescence quantum yields (PLQYs; 73.9% and 80.8% at 12 and 6 wt %, respectively; Table 1) of Pt-X-3 in the film of TCTA:B3PYMPM double hosts are not high enough. For this reason, we applied two additional tetradentate Pt(II) complexes Pt-X-2 and Pt-X-4 as single emitter in color-tunable OLEDs with CHIDEL structure, because of the higher energy of monomer emission of the former and the higher PLAY of the latter. The optimized EML structure for Pt-X-2 was TCTA: B3PYMPM: Pt-X-2 (26 wt %, 10 nm)/TCTA: B3PYMPM: Pt-X-2 (8 wt %, 10 nm), while that for Pt-X-4 was TCTA: B3PYMPM: Pt-X-4 (18 wt %, 10 nm)/TCTA: B3PYMPM: Pt-X-4 (8 wt %, 10 nm). Normalized EL spectra of Pt-X-2 and Pt-X-4 devices at various driving voltages are shown in FIGS. 5a and 5b, respectively. The emission color of the Pt-X-2 device shifted from yellowish-white to greenish-white, with CIE coordinates from (0.47, 0.44) to (0.36, 0.48), when the driving voltage increased from 3 to 11 V (FIG. 5c). Of note, a high color rendering index (CRI) of 82 was achieved at 5 V. Similar to that of the Pt-X-3 device, the emission color of the Pt-X-4 device shifted from orange, with CIE coordinates of (0.56, 0.43), to yellowish-green, with CIE coordinates of (0.42, with increasing driving voltage from 3 to 11 V. As shown in FIG. 5c, the color-span range of Pt-X-2 device was relatively narrow when compared to those of Pt-X-3 and Pt-X-4 devices. PL spectra of 100-nm-thick films with Pt-X-2 (26 wt %) and Pt-X-4 (18 wt %) in TCTA: B3PYMPM co-host are shown in FIG. 12. Profound difference between PL and EL spectra could be observed for Pt-X-4 while only slight difference between PL and EL spectra of Pt-X-2, suggesting that trapping-and-energy-transfer mechanism play an important role in the color-tuning process of the Pt-X-4 device with a CHIDEL structure while the shift of recombination zone may be the main mechanism for the Pt-X-2 device with a CHIDEL structure.

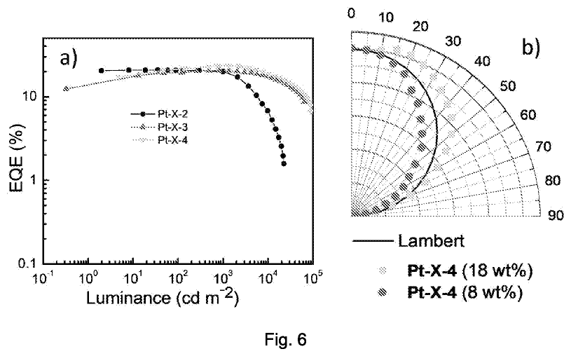

The EQE-luminance characteristics of the devices with Pt-X-2, Pt-X-3, and Pt-X-4 are depicted in FIG. 6a; maximum EQEs of 20.75, 20.67, and 23.23% were achieved, respectively. At a high luminance of 1000 cd m⁻², the EQE of the Pt-X-3 device slightly decreased to 20.58%, corresponding to an efficiency roll-off of less than 2%. For the Pt-X-4 device, a maximum EQE of 23.23% was achieved at 1300 cd m⁻². At higher luminance of 5000 and 10000 cd m⁻², the efficiency roll-offs of both the Pt-X-3 and Pt-X-4 devices were small, at 8.73% and 15.50% for the former and 9.38% and 19.97% for the latter, respectively. Compared to those of Pt-X-3 and Pt-X-4 devices, the efficiency roll-off of the Pt-X-2 device was profound at high luminance beyond 2000 cd m⁻², being 49.5% and 67.8% at 5000 and 10000 cd m⁻², respectively. We attributed such strong efficiency roll-off of the Pt-X-2 device to the long emission lifetime of Pt-X-2 monomers. The emission lifetimes of monomer and aggregate states of Pt-X-2 were 11.5 and 2.4 μs, respectively. With the increase of luminance, the monomer emission of the Pt-X-2 device became stronger (see FIG. 5a) and the device efficiency therefore strongly dropped caused by triplet-triplet annihilation due to the longer emission lifetime of Pt-X-2 monomers. In addition to comparing the EQE at high luminance, typically 1000 cd m⁻², with the maxim. EQE, the critical current density J₉₀, i.e. the current density at which the EQE drops to 90% of its maximum value, can also be used to evaluate the efficiency roll-off of OLEDs. In our case, as depicted in FIG. 11, J₉₀ was 0.28, 23.51, and 14.92 mA cm⁻² for the devices with Pt-X-2, Pt-X-3, and Pt-X-4, respectively.

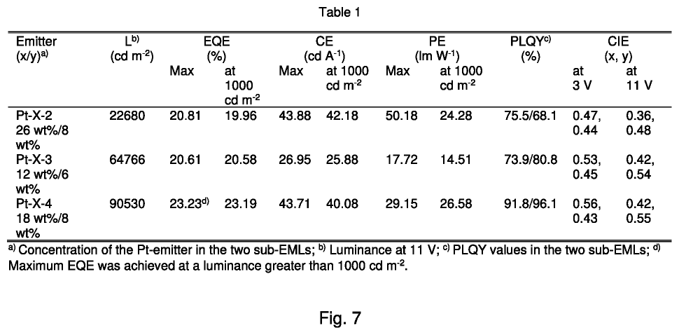

In addition to PLAY, the EQE value of an OLED is also a function of the out-coupling efficiency, which is strongly influenced by the horizontal transition dipole moment of the EML. A horizontal transition dipole moment has been observed in several OLEDs based on Ir(III) and Pt(II) complexes. Angular distributions of the EL intensities of Pt-X-4 in conventional TCTA: B3PYMPM co-host OLEDs with different dopant concentrations of 8 and 18 wt % were measured, and the results are shown in FIG. 6b. The EL distributions for both dopant concentrations did not match the Lambert distribution; a weak micro-cavity effect could be observed in the device with the lower concentration of Pt-X-4, while a pattern related to horizontal molecular orientation appeared when the concentration increased to 18 wt %. Such different EL angle distributions at different concentrations of Pt-X-4 suggest that the horizontal molecular direction is preferred in the aggregation states of Pt-X-4. As shown in FIG. 13a, the phenomenon that the emission intensity of aggregation states of Pt-X-4 increased with increasing angle relative to that of the monomer emission could be a result of the different horizontal dipole ratio (Θ) between monomer and aggregation states of Pt-X-4. By assuming the charge balance factor as 1, the out-coupling efficiency of a phosphorescent OLED can be calculated by its EQE and PLAY of its EML. As depicted in FIG. 13b, the EQEs of the Pt-X-4 devices with dopant concentrations of 8 and 18 wt % were 22.09% and 26.05%, respectively. According to the PLAY values of 96.1% (8 wt %) and 91.8% (18 wt %) for corresponding EMLs (see Table 1 of FIG. 7), the out-coupling efficiencies were estimated to be 22.98 and 28.38% for the devices with 8 and 18 wt % Pt-X-4, respectively. The high out-coupling efficiencies suggest horizontally aligned Θ (Θ>0.67) for both EMLs. Since the co-host TCTA: B3PYMPM used in these devices has been proved to be horizontally aligned, the contribution of emitting dopants to Θ can hardly be quantitatively calculated. Nonetheless, the relative higher out-coupling efficiency in the device with 18 wt % Pt-X-4 indicated that the aggregation states of Pt-X-4 could be more favorable to enhance Θ of the EML.

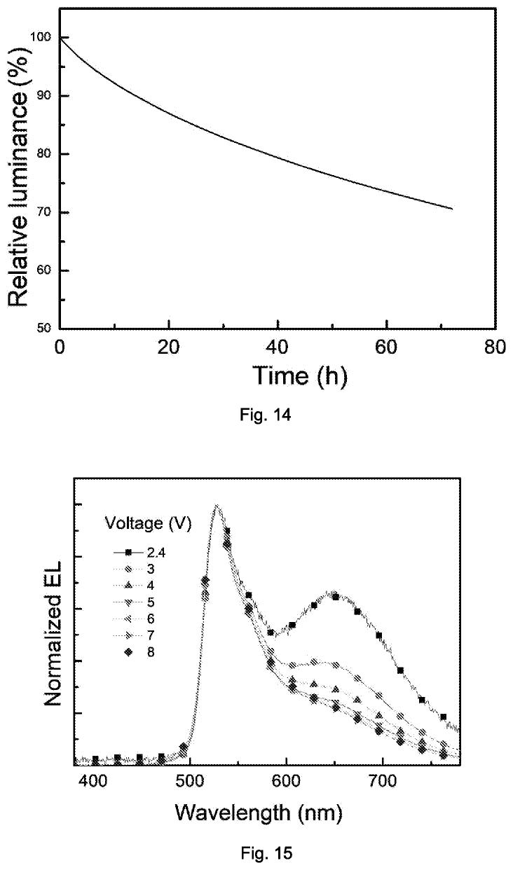

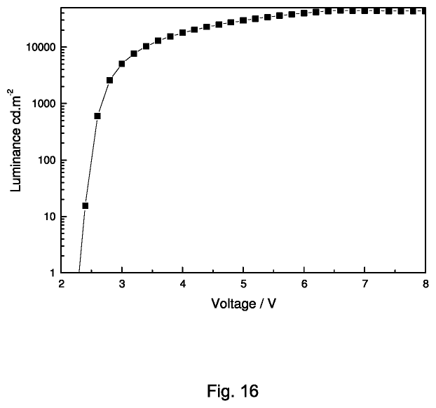

A preliminary examination of the operational stability of the OLEDs with Pt-X-4 under laboratory conditions demonstrated the duration to drop to 90% of the initial luminance (LT₉₀) of the Pt-X-4 OLEDs was 13.95 h (see FIG. 14). Considering the initial luminance (L₀) of 7000 cd m⁻², LT₉₀ at the L₀ of 100 cd m⁻² for the Pt-X-4 device was estimated to be 19105 h. (As the display of sensors, these color-tunable devices could function at around 100 cd m⁻².) FIG. 16 graphically depicts the Luminance-U curves of device with Pt-X-4.

As described herein, provided is a novel CHIDEL device structure for color-tunable OLEDs based on a single tetradentate Pt(II) emitter by combining recombination-zone-shift and trapping-and-energy-transfer mechanisms. Wide color-span range, high efficiency and low-efficiency roll-off were achieved in the CHIDEL devices based on Pt-X-2, Pt-X-3 and Pt-X-4. The EL distribution and long-term operational stability of Pt-X-4-based devices were also examined. The results show that the aggregation states of Pt-X-4 were horizontally oriented in the EML, and the device lifetime was longer than that of the Pt-X-4 monomers. Owing to the high efficiency and decent stability, simple-structured, color-tunable OLEDs with Pt-X-4 may find applications in wearable biomedical devices, such as real-time electrocardiogram monitors.

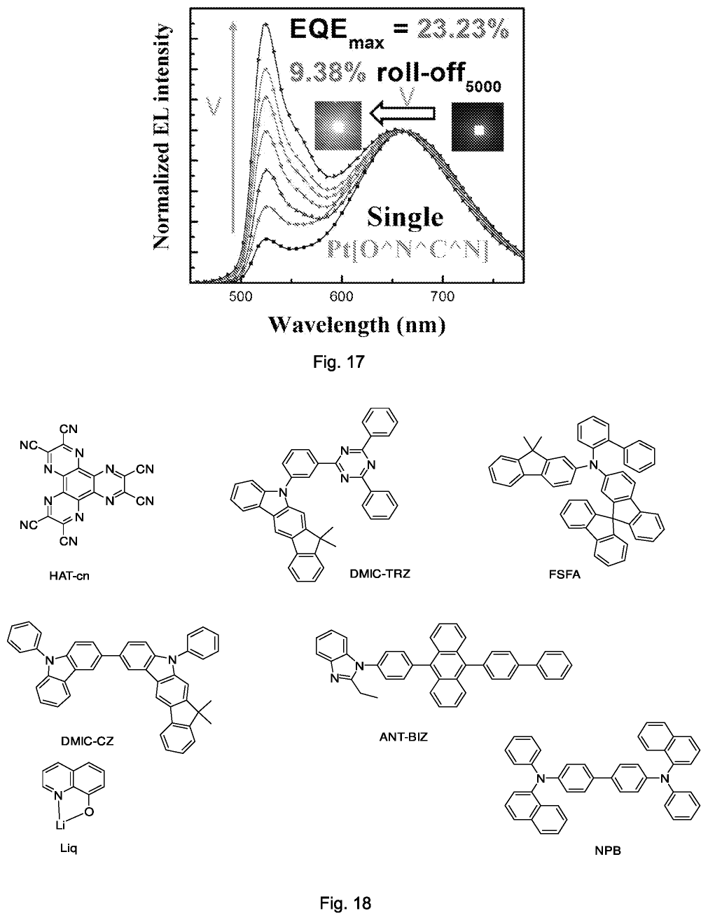

Referring to FIG. 17, characteristic data associated with the high-efficiency voltage-dependent color-tunable organic light-emitting diodes with a single tetradentate platinum(II) emitter having long operational lifetime are shown. The emission color can be tuned from warm white to nature white or from orange to yellowish green upon the emitter used. High EQE (23.23%), low efficiency roll-off, long-term stability (LT₉₀=19105 h) and continuously variable color enable these color-tunable OLEDs to find applications in smart wearable devices.

In one embodiment, a tetradentate platinum II based emitter has a first emission wavelength when subjected to a first driving voltage and a second emission wavelength different from the first emission wavelength when subjected to a second driving voltage different from the first driving voltage. In another embodiment, the tetradentate platinum II based emitter is a Pt[O\hat{ }N\hat{ }C\hat{ }N] complex. In yet another embodiment, the tetradentate platinum II based emitter has a monomer state and an aggregation state. In another embodiment, the second driving voltage can be at least twice the first driving voltage. In another embodiment, the first emission wavelength has a first hue selected from yellow, orange, red, green or blue, and the second emission wavelength has a second hue selected from yellow, orange, red, green or blue, the first hue and the second hue being different.

In one embodiment, an organic light-emitting diode comprises a first functional layer and a second functional layer configured to have a voltage driven across the first functional layer and the second functional layer; and an emissive layer between the first functional layer and the second functional layer, the emissive layer comprising a tetradentate platinum II based emitter having a first emission wavelength when subjected to a first driving voltage and a second wavelength different from the first wavelength when subjected to a second driving voltage different from the first driving voltage. In one embodiment, the doping concentration of the tetradentate platinum II based emitter in the emissive layer is from 1% by weight to 25% by weight, or from 3% by weight to 12% by weight.

### Device Description

The present disclosure describes emitters for use in voltage driven color tunable OLEDs, the OLED devices themselves, and methods of making and using such Pt(II) emitter OLED devices. In one aspect, the OLED devices implement a single emitter as described herein in order to generate light. A single emitter OLED simplifies the device structure and lowers manufacturing costs as compared to multiple-emitter OLEDs or more complicated OLEDs such as those that combine two or more sub-OLEDs. In one or more embodiments described herein, an emitter is provided whose emitting wavelength is variable in response to tuning driving voltage or current to achieve a desirable color or color temperature. As voltage is applied, the OLED produces varying monomer (e.g., 480-530 nm) and excimer (e.g., 600-650 nm) emission to produce light having a wavelength along the visible light spectrum (e.g., about 480 nm to 800 nm). By changing driving voltage or current, the ratio of the emitter's monomer and excimer emissions can be varied to create different colors.

The emitters and OLED devices described herein advantageously provide light emission characteristics that are suitable for typical OLED device application. The OLED devices as described herein include response rates between 1 μs and 1 ms and can function with voltage as low as 2.4V.

It is noted that the emitters described herein do not implement various conventional tactics to tune color. For example, the emitters do not tune color as a result of doping concentration (i.e., varying the concentrations of polar dopant molecules in the emissive layer or in the host material). The OLED devices described herein do not implement P-I-N doped layers as is known in the art. The hole transport layers are not p-doped and the electron transport layers are not n-doped.

Further, to produce certain color, the OLEDs described herein do not implement a multiple OLED arrangement in an array which each OLED is particularly tuned such that the average of the colors produces a desired color. Additionally, the OLEDs herein do not rely upon fluorescent molecules inserted into a phosphorescent complex, certain ligands to fine-tune the color of emission, or ligands to trap carriers. Rather, the voltage-dependent color-tunable nature of the OLEDs obviates such approaches.

The OLED devices described herein also do not necessarily include a carrier blocking layer or hole blocking layer disposed between adjacent emission layers in order to provide color tunable functionality. In one or more embodiments, the OLED devices described herein include a single emissive layer and utilize a co-host mixture in the emissive layer. In one or more embodiments, the OLED devices described herein include an emissive layer that is split into two emissive sub-layers. In a first emissive sub-layer, the emitter and host mixture is chosen to produce monomer emission as the dominant emission. In a second emissive sub-layer, the emitter and host mixture is chosen to produce excimer or aggregation-state emission as the dominant emission.

A color tunable OLED structure can have a single emitter as in one or more embodiments described herein is illustrated as a non-limiting example. The OLED includes a pair of electrodes corresponding to an anode and a cathode that sandwich a plurality of semiconductor layers between the two electrodes that cause electroluminescence when voltage is applied to the OLED. The anode and cathode comprise metallic materials for conducting electricity, such as the following non-limiting examples: aluminum, gold, magnesium, or barium for the cathode, and indium tin oxide (“ITO”) for the anode. The anode and cathode can have any thicknesses, for example, between 100-200 nm. In one or more embodiments, the anode lays further on top of a substrate. The substrate emits the light created by the OLED and is typically made of transparent material. For example, the substrate can be made of glass or a transparent polymer. A hole injection layer (“HIL”) and a hole transport layer (“HTL”) are layered on top of the anode. These layers play a role in the adjustment of electron/hole injection to attain transport balance of charge carriers in the emissive layer of the OLED. In one or more embodiments, the HIL has a thickness, for example, between 1-nm. In one or more embodiments, the HTL has a thickness between 30-80 nm. The materials for the HIL and HTL are selected to maximize OLED efficiency. As some non-limiting examples, the HIL can comprise molybdenum trioxide (“MoO₃”) or hexaazatriphenylene-hexacarbonitrile (“HAT-CN”), and the HTL 120 can comprise Tris(4-carbazoyl-9-ylphenyl)amine (“TcTa”), N,N′-Di(1-naphthyl)-N,N′-diphenyl-(1,1′-biphenyl)-4,4′-diamine (“NPB”) or di-4-tolylaminophenyl cyclohexane (“TAPC”). In one or more embodiments, the HTL includes two complementary sub-layers. For example, a first sub-layer of the HTL can include deposited TAPC or NPD, and a second sub-layer can include deposited TcTa. Exemplary compound structures deposited in HIL and HTL are shown below.

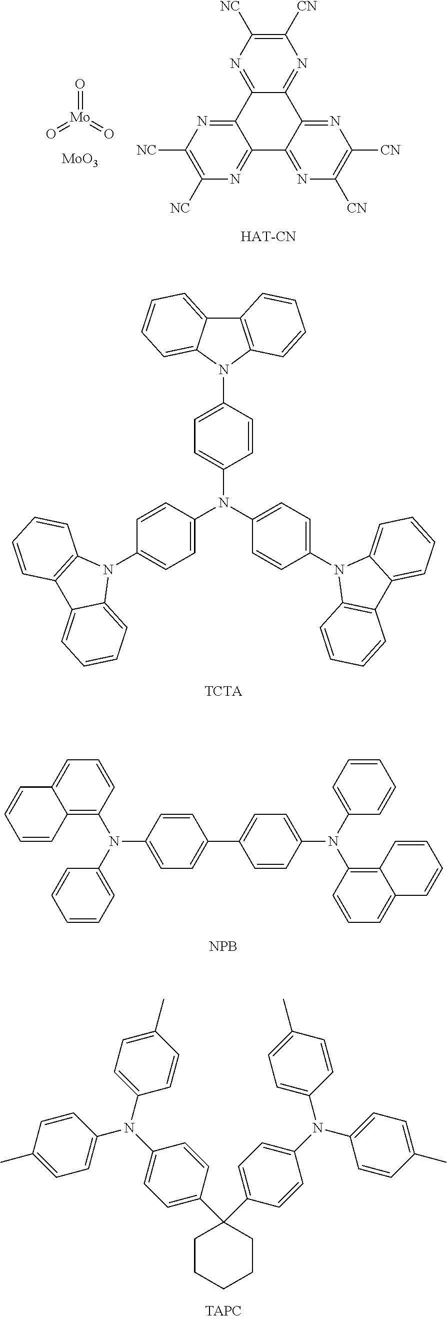

The emissive layer is arranged on top of HTL. In one or more embodiments, the emissive layer has a thickness between 10-30 nm. In one or more embodiments, the emissive layer includes one or more host materials mixed with an emitter formed by the compounds described herein. The host materials may be formed of a single host (i.e., one host mixed with an emitter), or may be formed as a co-host mixture (i.e., two hosts mixed with an emitter). The emitter is added to the host materials as a percentage of total weight. The single emitter emits light when voltage is applied to the emissive layer.

In one or more embodiments, the emissive layer is a single layer structure that implements a co-host mixture (e.g., two host materials and an emitter). In other embodiments, the emissive layer is two separate emissive sub-layers in which an emitter is mixed with one or more hosts in each sub-layer (“double EMLs”). For example, the emissive layer can be a single host double EML, in which a first host is mixed with the emitter in a first emissive sub-layer, and a second host is mixed with the emitter in a second emissive sub-layer. The first host can be the same or different from the second host. In still other embodiments, the emissive layer is a co-host double EML structure in which the first sub-layer includes two host materials mixed with the emitter, and the second sub-layer includes two host materials also mixed with the emitter. The co-host materials in the first and second sub-layers can be the same or different. In still further embodiments, the emissive layer is arranged as a mixed single/co-host double EML. For example, the first sub-layer can include a first host mixed with the emitter, whereas the second sub-layer can include a second host and a third host mixed as co-hosts with the emitter. The first, second and third hosts can be made of the same or different materials.

As some non-limiting examples, the host materials can be TcTa, 1,3-Bis(N-carbazolyl)benzene (“MCP”), 4,6-Bis(3,5-di-3-pyridylphenyl)-2-methylpyrimidine (“B3PymPm”), or 2,6-bis(3-(9H-Carbazol-9-yl)phenyl)pyridine (“26Dczppy”). In a particular embodiment, the emissive layer 125 is a co-host single layer structure that includes TcTa and B3PymPm as co-hosts and a platinum complex emitter (e.g., Pt-X-3 or Pt-X-5) of x % by weight of the hosts, in which x is, for example, between 2% and 30%.

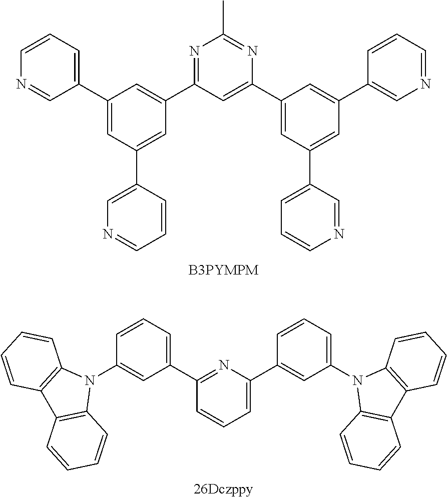 [SMILES: Cc1nc(-c2cc(-c3cccnc3)cc(-c3cccnc3)c2)cc(-c2cc(-c3cccnc3)cc(-c3cccnc3)c2)n1 ; c1cc(-c2cccc(-c3cccc(-n4c5ccccc5c5ccccc54)c3)n2)cc(-n2c3ccccc3c3ccccc32)c1]

An electron transport layer (“ETL”) and an electron injection layer (“EIL”) are arranged on top of the emissive layer and below the cathode. These layers provide high electron affinity and high electron mobility to the OLED for electrons to flow across the various OLED layers. In one or more embodiments, the ETL has a thickness between 30-80 nm. In one or more embodiments, the EIL has a thickness of 1-5 nm. In one or more embodiments, additional electron transporting materials are added to ETL and EIL to facilitate electron emission. The materials for the ETL and EIL are selected to maximize OLED efficiency. As some non-limiting examples, the ETL can comprise B3PymPm, 1,3,5-Tri(m-pyridin-3-ylphenyl)benzene (“TmPyPb”), 2,4,6-tris[3′-(pyridin-3-yl)biphenyl-3-yl]-1,3,5-triazine (“TmPPPyTz”), or 2,2′,2″-(1,3,5-Benzinetriyl)-tris(1-phenyl-1-H-benzimidazole) (“TPBi”). As some non-limiting examples, the EIL can comprise LiF, 8-hydroxy-quinolinato lithium (“Liq”), Cs, or CsF.

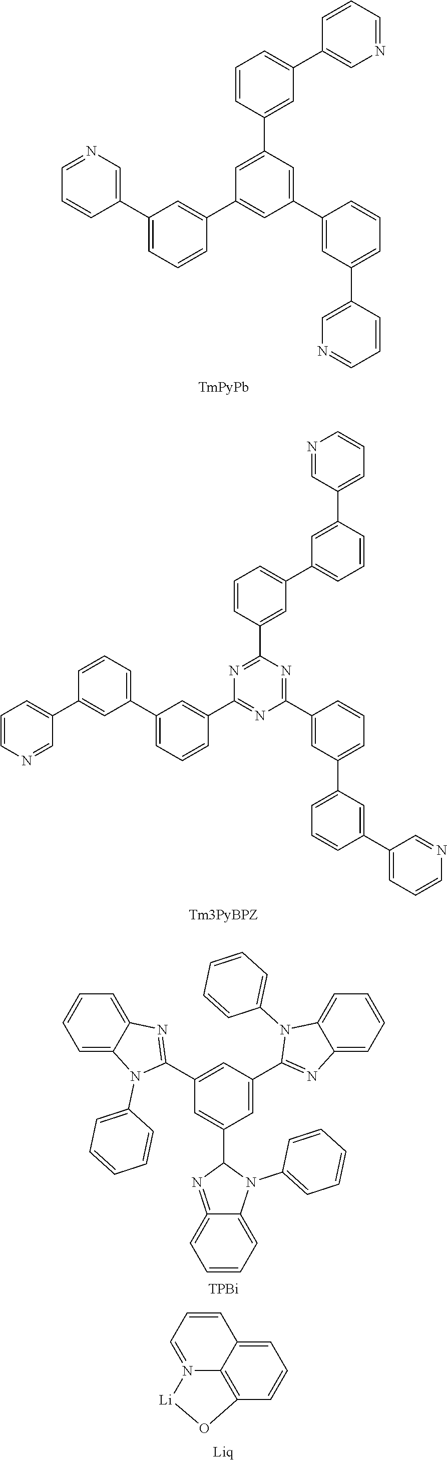

In one or more embodiments, the emitter used as a dopant in the emissive layer is a metal complex having square planar chemical structure. For example, the metal complex is a platinum complex. Platinum complexes are preferable as they have a rigid ligand scaffold with polydentate chelates to minimize structural distortion upon excitation, have an extended π-conjugation of ligand, have a strong δ-donation (e.g., O\hat{ }N\hat{ }C\hat{ }N with deprotonated C-donor) to ensure strong metal-ligand interaction, and have a high metal-character or charge transfer involvement in the emissive state (i.e., a short emission lifetime for the emitter). In one or more embodiments, the emitter is a compound having a structure form of Pt(O\hat{ }N\hat{ }C\hat{ }N).

In one aspect, the voltage-dependent tunable emitters described herein utilize the different states of single emitter to create light of different colors across the visible light spectrum. The compounds herein produce white light by applying voltage to produce complementary monomer and aggregation-state (e.g., excimer) emission when excited. This balance produces a high photoluminescence quantum yield and has a short emission lifetime (on the order of 100 ns to 10 μs), which lead to a high CRI and produce highly efficient OLED lighting. In one or more embodiments, the devices described herein can additionally utilize double host doping or double emissive layers to increase the color tuning range greatly, increase brightness (>80,000 cd/m²) and suppress efficiency roll-off at high luminance (from 1000 cd/m² to 5000 cd/m²). Double host doping (or co-host doping) is when a complex dopant is added to a two host mix within a single emissive layer.

### Experimental Section

Materials: HAT-CN, TAPC, TCTA, B3PYMPM, T2T and TmPyPb were purchased from Luminescence Technology Corp. All of these materials were used as received. Pt-X-2, Pt-X-3 and Pt-X-4 were synthesized as described previously, and purified by gradient sublimation before use.

PLQY measurement Samples of Pt(II) complexes doped in TCTA: B3PYMPM co-host at a suitable ratio were prepared by co-deposition in a Kurt J. Lesker SPECTROS vacuum deposition system with a base pressure of 10⁻⁸ mBar. The substrate was a 1 cm×1 cm quartz plate, and the thickness was 100 nm for all samples. The emission spectra and emission quantum efficiency of the thin films were assessed using a Hamamatsu absolute PL quantum yield spectrometer C11347.

Device Fabrication and Characterization: OLEDs were fabricated in a Kurt J. Lesker SPECTROS vacuum deposition system with a base pressure of 10⁻⁸ mBar. In the vacuum chamber, organic materials were thermally deposited in sequence at a rate of ≈0.1 nm s⁻¹. The doping process in the emitting layer was realized by co-deposition technology. Afterward, LiF (1.2 nm) and Al (100 nm) were thermally deposited at rates of 0.03 and 0.2 nm s⁻¹, respectively. Film thicknesses were determined in situ using calibrated oscillating quartz crystal sensors.

EL spectra, J-L-V characteristics, CIE coordinates, CRI, EQE, CE and PE were measured using a Keithley 2400 source-meter and an absolute external quantum efficiency measurement system (C9920-12, Hamamatsu Photonics). EL distribution was measured with an angle-dependent device testing system (C9920-11, Hamamatsu Photonics). All devices were characterized at room temperature without encapsulation.

Device lifetime measurement The OLEDs used to evaluate the long-term stability of Pt-X-4 had a device structure of ITO/HAT-CN (5 nm)/NPB (20 nm)/FSFA (15 nm)/DMIC-TRZ: DMIC-CZ: Pt-X-4 (8 wt %)/ANT-BIZ (20 nm)/Liq (1 nm)/Al (100 nm). The chemical structures of NPB, FSFA, DMIC-TRZ, DMIC-CZ, ANT-BIZ, and Liq are depicted in FIG. 18, Supporting Information. All materials except for Pt-X-4 were purchased from PURI materials (Shenzhen, China). They were used as received without further purification. The OLEDs were fabricated in a Kurt J. Lesker SPECTROS vacuum deposition system and encapsulated in a 200-nm-thick Al₂O₃ thin film deposited by atomic layer deposition (ALD) in a Kurt J. Lesker SPECTROS ALD system.

FIG. 18 depicts chemical structures of the supporting organic materials used to construct the OLED described herein for lifetime measurement.

Exemplary device structures include:

ITO (substrate)/HAT-cn (5 nm)/FSFA (15 nm)/DMIC-Trz: DMIC-Cz: Pt (II) x wt % (15 nm)/ANT-BIZ (20 nm)/Liq (1 nm)/Al(100 nm).

Wherein, x represents 6 wt %˜20 wt %, Pt(II) represents Pt-X-4, Pt-X-3, Pt-X-2-n or other Pt(II) emitters with both monomer and aggregation emissions.

Here, Pt-X-4 is used as emitter fist. The results are as follows: Device structure: ITO/HAT-CN (5 nm)/NPB (20 nm)/FSFA (15 nm)/DMIC-TRZ: DMIC-CZ: Pt-X-4 (8 wt %)/ANT-BIZ (20 nm)/Liq (1 nm)/Al (100 nm).

The key performance of device operational lifetime:

| L₀ cd · m⁻² | LT₉₇ hr | LT₉₅ hr | LT₉₀ hr | LT₅₀ hr |
|---|---|---|---|---|
| ~7000 | 3.118 | 5.69 | 13.95 | >150 |
| 1000 | 85.22 | 155.5 | 381.2 | >4099 |
| 100 | 4271 | 7794 | 19105 | >205442 |

As the display of sensors, these color-tunable devices could function at around 100 cd·m⁻². Thereby, we calculate the operational lifetime of Device at 100 cd·m⁻². LT₉₀ is as high as 19105 hours and LT₅₀ even beyond 200,000 hours.

Oled Efficiency:

| Doping | EQEₘₐₓ | CE max | PE max |
|---|---|---|---|
| concentration | % | Cd/A | Lm/W |
| 2% | 8.85 | 29.5 | 38.7 |
| 4% | 8.2 | 20.7 | 27.1 |
| 6% | 7.6 | 17.9 | 21.6 |

### Example 2

The stable color tunable OLED with single emitter Pt-X-4.

The device structure is:
Device 1: ITO (substrate)/HAT-cn (5 nm)/Pt-301 (160 nm)/FSFA (5 nm)/DMIC-TRZ: DMIC-CZ: Pt-x-4 (15 nm)/ANT-BIZ (20 nm)/Liq (1 nm)/AL (100 nm)
Wherein, HAT-cn is hole-injecting layer, Pt-301 is hole-transporting layer, FSFA is used to transporting hole and/or as electron-blocking layer, ANT-BIZ is electron-transporting layer, Liq is electron-injecting layer, and Al is used as negative electrode. In the emissive layer, DMIC-TRZ and DMIC-CZ are mixed together as hosts with molar ratio of 1:1, and doped with 10 wt % Pt-X-4; here, Pt-X-4 is the single emitter.
Device 2: ITO (substrate)/HAT-cn (5 nm)/Pt-301 (160 nm)/FSFA (5 nm)/DMIC-TRZ: DMIC-CZ: Pt-x-4 4 wt % (EML1, 10 nm)/DMIC-TRZ: DMIC-CZ: Pt-X-4 10 wt % (EML2, 10 nm)/ANT-BIZ (20 nm)/Liq (1 nm)/AL (100 nm) Wherein, HAT-cn is hole-injecting layer, Pt-301 is hole-transporting layer, FSFA is used to transporting hole and/or as electron-blocking layer, ANT-BIZ is electron-transporting layer, Liq is electron-injecting layer, and Al is used as negative electrode. In the emissive layer 1 (EML1), DMIC-TRZ and DMIC-CZ are mixed together as hosts with molar ratio of 1:1, and doped with 4 wt % Pt-X-4; In the emissive layer 2 (EML2), DMIC-TRZ and DMIC-CZ are mixed together as hosts with molar ratio of 1:1, and doped with 10 wt % Pt-X-4; here, Pt-X-4 is the single emitter.
Device 3: ITO (substrate)/HAT-cn (5 nm)/Pt-301 (160 nm)/FSFA (5 nm)/DMIC-TRZ: DMIC-CZ: Pt-X-2-n (15 nm)/ANT-BIZ (20 nm)/Liq (1 nm)/AL (100 nm)
Wherein, HAT-cn is hole-injecting layer, Pt-301 is hole-transporting layer, FSFA is used to transporting hole and/or as electron-blocking layer, ANT-BIZ is electron-transporting layer, Liq is electron-injecting layer, and Al is used as negative electrode. In the emissive layer, DMIC-TRZ and DMIC-CZ are mixed together as hosts with molar ratio of 1:1, and doped with 10 wt % Pt-X-2-n; here, Pt-X-2-n is the single emitter.
The selected device data of Device 1, 2 and 3 are listed as follows:

| | | LT90 | LT90 |
|---|---|---|---|
| | EQEₘₐₓ | (1000 cd/m²) | (100 cd/m²) |
| Device No. | % | hr | hr |
| 1 | 8.9 | 392 | 19992 |
| 2 | 8.2 | 403 | 20553 |
| 3 | 7.8 | 0.5 | 25.5 |

The chemical structure of Pt-X-2-n and Pt-X-4 are listed below:

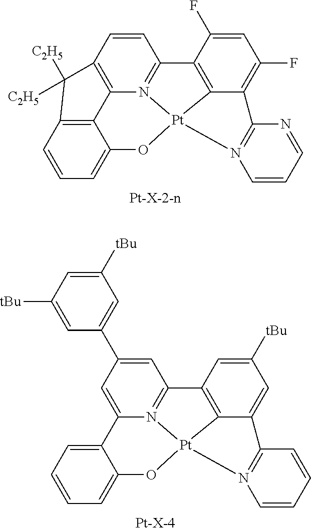

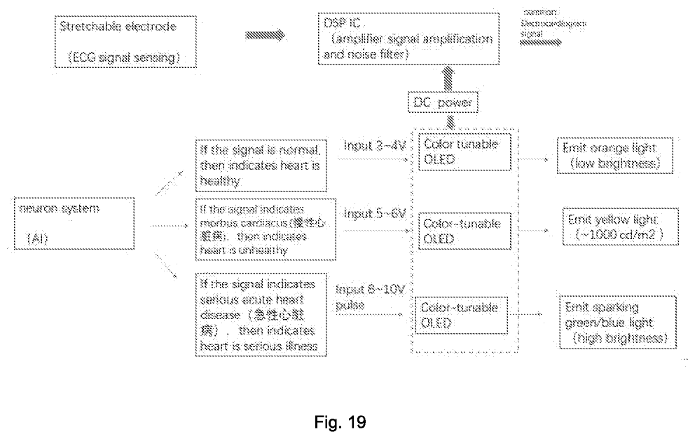

FIG. 19 depicts a system incorporating the color-tunable OLEDs described herein.

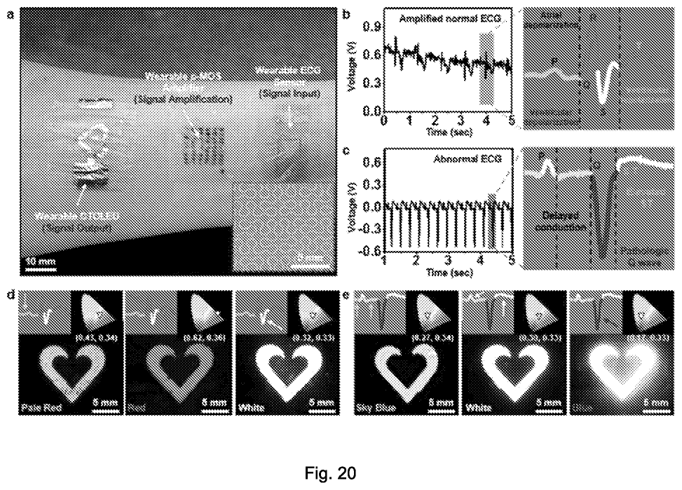

FIG. 20 (FIG. 20a-20e) depict the potential applications associated with the color-tunable OLEDs described herein (Ja, Hoon Koo, et al. ACS Nano 2017, 11, 10032-10041).

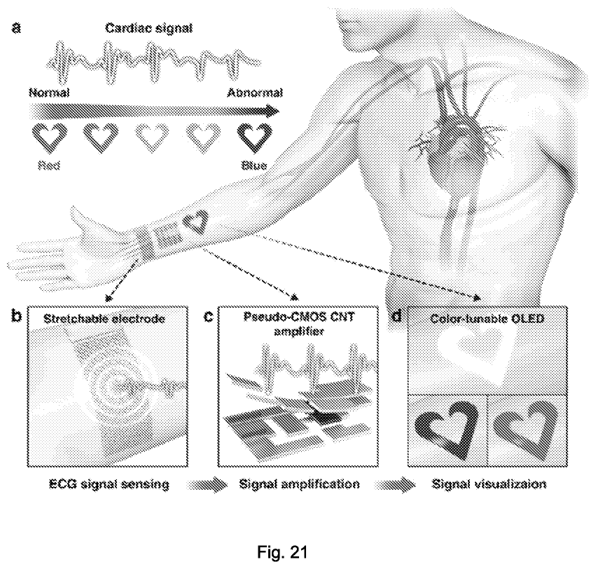

FIG. 21 (FIG. 21a-21d) depict potential wearable health-monitor device applications associated with the color-tunable OLEDs described herein (Ja, Hoon Koo, et al. ACS Nano 2017, 11, 10032-10041).

Unless otherwise indicated in the examples and elsewhere in the specification and claims, all parts and percentages are by weight, all temperatures are in degrees Centigrade, and pressure is at or near atmospheric pressure.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

While the invention is explained in relation to certain embodiments, it is to be understood that various modifications thereof will become apparent to those skilled in the art upon reading the specification. Therefore, it is to be understood that the invention disclosed herein is intended to cover such modifications as fall within the scope of the appended claims.

1. A color-tunable electroluminescent device, comprising:
a positive electrode and a negative electrode configured to have a voltage driven across the two electrodes; and
at least three organic layers between the two electrodes; wherein at least one organic layer is an emissive layer, and at least one organic layer is hole-transporting layer, one organic layer is electron-transporting layer; at least one layer clinging to the positive electrode is hole-injecting layer, wherein the layer is composed of organic materials or inorganic materials; at least one layer clinging to the negative electrode is electron-injecting layer, wherein the layer is composed of organic materials or inorganic materials;
wherein the electron-transporting layer or hole-transporting layer is composed of one organic material or is mixed with two or more organic materials or is mixed with two or more organic or inorganic materials;
wherein in the emissive layer(s), at least one emissive layer comprises one luminescent material and one or more host materials; and
wherein in the emissive layer(s), the luminescent material is metal complex or organic material, and the luminescent material has monomer emissive state and at least one aggregation emissive state; wherein the spectra peaks between at least two emissive states have a span of at least 50 nm.

2. The color-tunable electroluminescent device according to claim 1, wherein the materials used in hole-injecting layer, hole-transporting layer, electron-transporting layer and electron-injecting layer are but not limited to HAT-cn, NPB, ANT-BIZ and Liq, respectively; wherein the hole-transporting material can be also FAFA or Pt-301.

3. The color-tunable electroluminescent device according to claim 1, wherein the emissive layer (s) is (are) composed of one or two layers; wherein at least one emissive layer comprising but not limited to the organic materials as follows: DMIC-TRZ, DMIC-CZ and mixed with Pt(II) (O\hat{ }N\hat{ }C\hat{ }N) complex.

4. The color-tunable electroluminescent device according to claim 3, wherein the emissive layers are composed of two host materials DMIC-TRZ/DMIC-CZ, and mixed with luminescent materials; wherein the molar ratio of the two host materials is between 1:2˜2:1; the doping concentration of luminescent material is between 6 wt % to wt %%.

5. The color-tunable electroluminescent device according to claim 1, wherein the luminescent material is Pt complex or Pd complex.

6. The color-tunable electroluminescent device according to claim 1, wherein the hole-injecting layer has a thickness is between 0.5˜10 nm; wherein the thickness of hole-transporting layer NPB is between 15˜50 nm; wherein the thickness of hole-transporting layer Pt-301 is between 50˜200 nm; the thickness of layer FSFA is between 10˜30 nm; wherein the thickness of electron-transporting layer is between 15˜50 nm; wherein the thickness of electron-injecting layer is between 0.5˜5 nm.

7. The color-tunable electroluminescent device according to claim 1, providing a first voltage to the OLED device to cause the OLED device to emit a first color with a first spectrum; and adjusting the first voltage to a second voltage to the device to cause the OLED device to emit a second color with a second spectrum; wherein the gap between the first voltage and the second voltage is at least 0.5 V; wherein the ratio between the monomer state and the aggregation state of emitter is variational when applied two different voltage; wherein the tuning range of applied voltage is between 2.4V˜15 V.

8. A color-tunable electroluminescent device, comprising:
a positive electrode and a negative electrode configured to have a voltage driven across the two electrodes; and
at least three organic layers between the two electrodes; wherein one organic layer is an emissive layer, and at least one organic layer is hole-transporting layer, one organic layer is electron-transporting layer; at least one layer clinging to the positive electrode is hole-injecting layer, wherein the layer is composed of organic materials or inorganic materials; at least one layer clinging to the negative electrode is electron-injecting layer, wherein the layer is composed of organic materials or inorganic materials;
wherein the electron-transporting layer or hole-transporting layer is composed of one organic material or is mixed with two or more organic materials or is mixed with two or more organic or inorganic materials; and
wherein in the emissive layer(s), two or more host materials are mixed together, and one luminescent material is doped into this layer; wherein the luminescent material is metal complex or organic material, and it has monomer emissive state and at least one aggregation emissive state; wherein the spectra peaks between at least two emissive states have a span of at least 50 nm.

9. A color-tunable electroluminescent device, comprising:
a positive electrode and a negative electrode configured to have a voltage driven across the two electrodes; and
at least four organic layers between the two electrodes; wherein at least two or more organic layers are emissive layers, and at least one organic layer is a hole-transporting layer, one organic layer is an electron-transporting layer; at least one layer clinging to the positive electrode is a hole-injecting layer, wherein the layer is composed of organic materials or inorganic materials; at least one layer clinging to the negative electrode is an electron-injecting layer, wherein the layer is composed of organic materials or inorganic materials;
wherein the electron-transporting layer or hole-transporting layer is composed of one organic material or is mixed with two or more organic materials or is mixed with two or more organic or inorganic materials;
wherein in the emissive layer(s), at least two emissive layer comprises one luminescent material and one or more host materials; and
wherein in the emissive layer(s), the luminescent material is metal complex or organic material, and the luminescent material has monomer emissive state and at least one aggregation emissive state; wherein the spectra peaks between at least two emissive states have a span of at least 50 nm.

10. The color-tunable electroluminescent device according to claim 8, wherein the materials used in the hole-injecting layer, hole-transporting layer, electron-transporting layer and electron-injecting layer comprises HAT-cn, NPB, ANT-BIZ and Liq, respectively; or wherein the hole-transporting material comprises FAFA or Pt-301.

11. The color-tunable electroluminescent device according to claim 8, wherein the emissive layer is composed of two host materials DMIC-TRZ/DMIC-CZ, and mixed with luminescent materials; wherein the molar ratio of the two host materials is between 1:2˜2:1; the doping concentration of luminescent material is between 6 wt % to 20 wt %.

12. The color-tunable electroluminescent device according to claim 9, wherein the emissive layers are composed of two or more emissive layers; wherein at least one emissive layer is mixed with two host materials DMIC-TRZ/DMIC-CZ, and doped with a luminescent material of certain concentration; wherein the molar ratio of the two host materials is between 1:2˜2:1; wherein the doping concentration of luminescent material is between 1 wt %˜6 wt %; wherein the thickness of this emissive layer is between 5˜20 nm; or
wherein at least one emissive layer is composed of one host material doped with a luminescent material of certain concentration; wherein the doping concentration of luminescent material is between 1 wt %˜6 wt %; wherein the thickness of this emissive layer is between 5˜20 nm.

13. The color-tunable electroluminescent device according to claim 9, wherein one emissive layer is mixed with two host materials DMIC-TRZ/DMIC-CZ, and doped with a luminescent material with certain concentration; wherein the molar ratio of the two host materials is between 1:2˜2:1; wherein the doping concentration of luminescent material is between 6 wt %˜20 wt %; wherein the thickness of this layer between 5˜20 nm.

14. The color-tunable electroluminescent device according to claim 8, wherein the hole-injecting layer has a thickness is between 0.5˜10 nm; wherein the thickness of hole-transporting layer NPB is between 15˜50 nm; wherein the thickness of hole-transporting layer Pt-301 is between 50˜200 nm; the thickness of layer FSFA is between 10˜30 nm; wherein the thickness of electron-transporting layer is between 15˜50 nm; wherein the thickness of electron-injecting layer is between 0.5˜5 nm.

15. The color-tunable electroluminescent device according to claim 8, providing a first voltage to the OLED device to cause the OLED device to emit a first color with a first spectrum; and adjusting the first voltage to a second voltage to the device to cause the OLED device to emit a second color with a second spectrum; Wherein the gap between the first voltage and the second voltage is at least 0.5 V; wherein the ratio between the monomer state and the aggregation state of emitter is variational when applied two different voltage; wherein the tuning range of applied voltage is between 2.4V˜15 V.

16. The color-tunable electroluminescent device according to any of claim 1, wherein the emitter has a chemical structure according to formula (I): 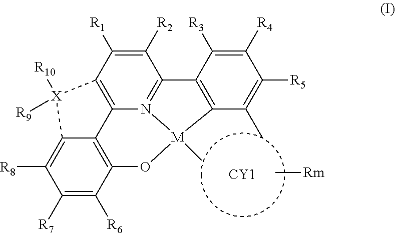
wherein, M is selected from Pt or Pd;
CY1 is independently selected from 5-membered or 6-membered carbon ring, nitrogen heterocyclic ring, sulfur heterocyclic ring, or their derivative with specific functional groups;
X connect the two 6-member ring in formula (I); wherein X is selected from C atom or O atom;
R₉ and R₁₀ are selected from a linear or branched alkyl radical having from 1 to 4 carbon atoms and optionally with at least one functional group;
X, R₉ or R₁₀ exist or don't exist;
R₁-R₈ are selected from the atoms or groups as follows:
hydrogen, halogen, hydroxyl, an unsubstituted alkyl, a substituted alkyl, cycloalkyl, an unsubstituted aryl, a substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, or an alkoxycarbonyl group; and
Rm connects to CY1 and is selected from atoms or groups as follows: hydrogen, halide, alkyl, cycloalkyl, heteroalkyl, arylalkyl, alkoxy, aryloxy, amino, silyl, alkenyl, cycloalkenyl, 5 heteroalkenyl, alkynyl, aryl, heteroaryl, acyl, carbonyl, carboxylic acids, ester, nitrile, sulfonyl, phosphino, and combinations thereof.

17. The color-tunable electroluminescent device according to claim 1, wherein the luminescent material has the chemical structure of formula (II): 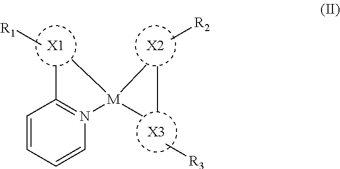
wherein X1, X2, and X3 are independently selected from 5-membered or 6-membered carbon ring, nitrogen heterocyclic ring, sulfur heterocyclic ring, or their derivative with specific functional groups. R₁, R₂ and R₃ are selected from a linear or branched alkyl radical having from 1 to 4 carbon atoms and optionally with at least one functional group.

18. The color-tunable electroluminescent device according to claim 1, wherein the luminescent material has the chemical structure of formula (III): 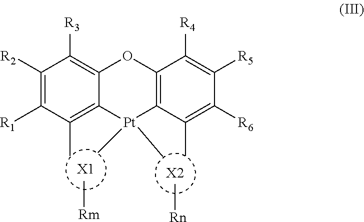
wherein X1 and X2 are independently selected from 5-membered or 6-membered carbon ring, nitrogen heterocyclic ring, sulfur heterocyclic ring, or their derivative with specific functional groups. R₁, R₂, R₃, R₄, R⁵ and R₆ are selected from a linear or branched alkyl radical having from 1 to 4 carbon atoms and
optionally with at least one functional group; Rm and Rn Rm connects to X1 and X2, respectively. They are selected from atoms or groups as follows: hydrogen, halide, alkyl, cycloalkyl, heteroalkyl, arylalkyl, alkoxy, aryloxy, amino, silyl, alkenyl, cycloalkenyl, 5 heteroalkenyl, alkynyl, aryl, heteroaryl, acyl, carbonyl, carboxylic acids, ester, nitrile, sulfonyl, phosphino, and combinations thereof.

19. The color-tunable electroluminescent device according to claim 1, the chemical structures of materials HAT-cn, NPB, ANT-BIZ, FSFA, DMIC-TRZ, DMIC-CZ, Pt-301 and Liq are as follows:

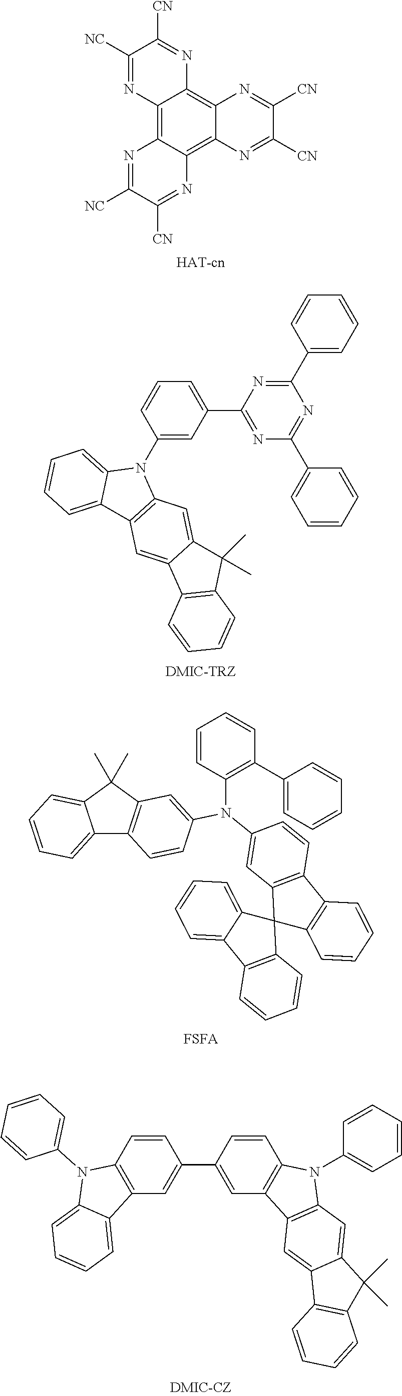 [SMILES: N#Cc1nc2c3nc(C#N)c(C#N)nc3c3nc(C#N)c(C#N)nc3c2nc1C#N ; CC1(C)c2ccccc2-c2cc3c4ccccc4n(-c4cccc(-c5nc(-c6ccccc6)nc(-c6ccccc6)n5)c4)c3cc21 ; CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2cc3c4cc(-c5ccc6c(c5)c5ccccc5n6-c5ccccc5)ccc4n(-c4ccccc4)c3cc21]

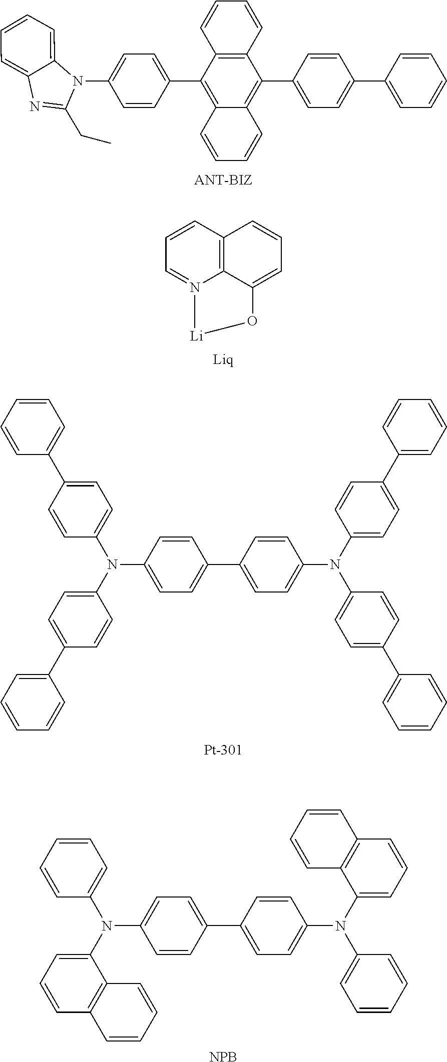

20. The color-tunable electroluminescent device according to claim 1, the organic layers are fabricated by vacuum-evaporation deposition method or spin-coating method or ink-printing method or roll-to-roll printing method.

21. The color-tunable electroluminescent device according to claim 1, are used to fixed visual display unit, mobile visual display unit, illumination unit, keyboard, clothes, ornaments, garment accessary, wearable devices, medical monitoring devices, wall paper, tablet PC, laptop, advertisement panel, panel display unit, household appliance, office appliance.
